(19) United States
(12) Patent Application Publication
(10) Pub. No.: US 2026/0112878 A1
(43) Pub. Date: Apr. 23, 2026

(54) BIDIRECTIONAL ELECTROSTATIC DISCHARGE DETECTOR

(71) Applicant: Micron Technology, Inc., Boise, ID (US)

(72) Inventors: James E. Davis, Meridian, ID (US); Kenneth W. Marr, Boise, ID (US); Souvick Mitra, Boise, ID (US); Tyler Klarr, Boise, ID (US); Jonathan W. Oh, Boise, ID (US); Naohisa Nishioka, Yokohama (JP); Yu Wu Su, Taichung (TW); Manu Sushruth, Hyderabad (IN)

(21) Appl. No.: 19/363,070

(22) Filed: Oct. 20, 2025

Related U.S. Application Data
(60) Provisional application No. 63/710,958, filed on Oct. 23, 2024.

(51) Int. Cl. H02H 3/08; H01L 23/60

(52) U.S. Cl. CPC H02H 3/08; H10W 42/60

(57) ABSTRACT

An apparatus may include a fuse coupled between a bidirectional electrostatic discharge (ESD) element and a first bond contact, the fuse is configured to receive an ESD discharge current generated between the first bond contact and a second bond contact, and the fuse is configured to blow in response to the ESD discharge current exceeding a threshold current magnitude, and a detector coupled to the bidirectional ESD element, the detector is configured to determine a state of the fuse.

### TECHNICAL FIELD

This application claims the benefit of U.S. Provisional Application No. 63/710,958, filed on Oct. 23, 2024, the contents of which are incorporated herein by reference.

### TECHNICAL FIELD

The present disclosure relates generally to semiconductor memory and methods, and more particularly, to apparatuses, systems, and methods for a bidirectional electrostatic discharge detector.

### BACKGROUND

Memory devices are typically provided as internal, semiconductor, integrated circuits in computers or other electronic systems. There are many different types of memory including volatile and non-volatile memory. Volatile memory can require power to maintain its data (e.g., host data, error data, etc.) and includes random access memory (RAM), dynamic random-access memory (DRAM), static random-access memory (SRAM), synchronous dynamic random-access memory (SDRAM), and thyristor random access memory (TRAM), among others. Non-volatile memory can provide persistent data by retaining stored data when not powered and can include NAND flash memory, NOR flash memory, and resistance variable memory such as phase change random access memory (PCRAM), resistive random-access memory (RRAM), and magnetoresistive random access memory (MRAM), such as spin torque transfer random access memory (STT RAM), among others.

Flash memory devices can include a charge storage structure, such as is included in floating gate flash devices and charge trap flash (CTF) devices, which may be utilized as non-volatile memory for a wide range of electronic applications. Flash memory devices may use a one-transistor memory cell that allows for high memory densities, high reliability, and low power consumption.

Memory cells in an array architecture can be programmed to a target state. For example, electric charge can be placed on or removed from the floating gate of a memory cell to put the cell into one of a number of data states. For example, a single level cell (SLC) can be programmed to one of two data states representing one of two units of data (e.g., 1 or 0). Multilevel memory cells (MLCs) can be programmed to one of more than two data states. For example, an MLC capable of storing two units of data can be programmed to one of four data states, an MLC capable of storing three units of data can be programmed to one of eight data states, and an MLC capable of storing four units of data can be programmed to one of sixteen data states. MLCs can allow the manufacture of higher density memories without increasing the number of memory cells since each cell can represent more than one unit of data (e.g., more than one bit). However, MLCs can present difficulties with respect to sensing operations as the ability to distinguish between adjacent data states may deteriorate over time and/or operation.

Electrostatic discharges (ESDs) can occur during the manufacturing of memory devices. An ESD can refer to a sudden flow of electricity between two electrically charged objects. The ESD can occur when contact or near contact occurs between the two electrically charged objects. The ESD can be a rapid transfer of charge that can potentially cause damage to components of the memory device.

### BRIEF DESCRIPTION OF THE DRAWINGS

The present disclosure will be understood more fully from the detailed description given below and from the accompanying drawings of various embodiments of the disclosure.

FIG. 1 is a prior art block diagram of devices to illustrate an electrostatic discharge between bonding contacts.

FIG. 2 is a prior art block diagram of devices to illustrate an electrostatic discharge between bonding contacts.

FIG. 3 illustrates an example of a system that utilizes a bidirectional electrostatic discharge detector in accordance with some embodiments of the present disclosure.

FIG. 4 illustrates an example of a system that utilizes a bidirectional electrostatic discharge detector in accordance with some embodiments of the present disclosure.

FIG. 5 illustrates an example of a system that utilizes a bidirectional electrostatic discharge detector in accordance with some embodiments of the present disclosure.

FIG. 6 illustrates an example of a system that utilizes a bidirectional electrostatic discharge detector in accordance with some embodiments of the present disclosure.

FIG. 7 illustrates an example of a system that utilizes a bidirectional electrostatic discharge detector in accordance with some embodiments of the present disclosure.

FIG. 8 illustrates an example of a system that utilizes a plurality of bidirectional electrostatic discharge detectors in accordance with some embodiments of the present disclosure.

### DETAILED DESCRIPTION

Aspects of the present disclosure are directed to a bidirectional electrostatic discharge detector. The bidirectional electrostatic discharge detector can be utilized to detect and determine that an electrostatic discharge has occurred in association with a first bond contact coming into contact or nearly comes into contact with a second bond contact. The bidirectional electrostatic discharge detector can detect electrostatic discharges while positioned on die.

An electrostatic discharge can refer to a sudden flow of electricity between two electrically charged objects caused by contact, an electrical short, and/or dielectric breakdown. The electrostatic discharge can occur in response to a difference in electrical potential between the two objects that is greater than a threshold current magnitude, which can lead to the rapid transfer of charge between the two objects. As described herein, electrostatic discharge can damage electronic components, particularly sensitive microelectronics, by causing electrical overstress. In industrial and electronics manufacturing settings, measures are taken to prevent electrostatic discharge to protect equipment and ensure safety.

Memory devices and/or other electrical devices can electrically connect a first substrate to a second substrate. For example, the first substrate can include a first plurality of bonding contacts and the second substrate can include a second plurality of bonding contacts that correspond to the first plurality of bonding contacts. In this example, the first substrate can be electrically bonded to the second substrate by electrically connecting the first plurality of bonding contacts to the second plurality of bonding contacts utilizing a bonding operation. Examples of bonding contacts include pins, pads, bumps, balls, etc.

An electrostatic discharge can occur between bonding contacts during the bonding operation. For example, the first plurality of bonding contacts can be aligned with corresponding bonding contacts of the second plurality of bonding contacts. In this example, the first plurality of bonding contacts can be brought into contact with the corresponding bonding contacts of the second plurality of bonding contacts. In this example, the electrostatic discharge can occur in response to the first plurality of bonding contacts making contact with the corresponding bonding contacts of the second plurality of bonding contacts. The electrostatic discharge can cause a voltage that can damage components coupled to the first substrate and/or the second substrate.

Previous systems and methods may not be able to accurately detect the voltage caused by the electrostatic discharge and/or determine whether the voltage caused by the electrostatic discharge will damage the components of the first substrate and/or the second substrate. If the voltage and/or current of the electrostatic discharge is not detected during the bonding operation, the resulting device may include damaged components within the first substrate and/or second substrate that are not identified. This can result in end products that have lower performance and/or non-functional components.

In order to address these and other deficiencies of current approaches, embodiments of the present disclosure can be used to monitor electrostatic discharges during the bonding operation and determine whether the voltage and/or current of the electrostatic discharge exceeds a threshold current magnitude (e.g., threshold electrostatic discharge). In these embodiments, an electrostatic discharge detector can be utilized to determine whether an electrostatic discharge occurs, an amplitude of the voltage or current of the electrostatic discharge, and/or a contact on the substrate where the electrostatic discharge occurred. In some embodiments, this can be achieved utilizing an on-chip electrostatic discharge detector. In addition, the electrostatic discharge detector can be tuned for specific types of substrates and/or specific types of electrical bond contacts.

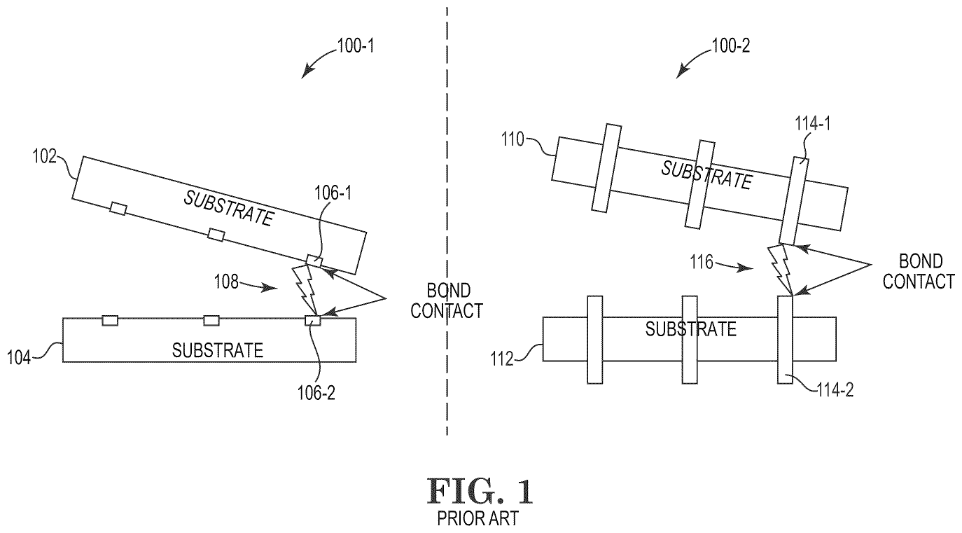

FIG. 1 is a prior art block diagram of devices 100-1, 100-2 to illustrate an electrostatic discharge 108, 116 between bonding contacts. FIG. 1 illustrates a first device 100-1 that can include a first substrate 102 that utilizes a first bond contact 106-1 that can be coupled to a second bond contact 106-2 of a second substrate 104. In a similar way, FIG. 1 illustrates a second device 100-2 that can include a first substrate 110 that utilizes a first bond contact 114-1 that can be coupled to a second bond contact 114-2 of a second substrate 112.

The first device 100-1 can include a first substrate 102 that is to be electrically coupled to a second substrate 104. As described herein, the first substrate 102 can be electrically coupled to the second substrate 104 utilizing a bonding operation to electrically bond the first bond contact 106-1 to the second bond contact 106-2. The bonding operation can include electrically bonding a plurality of bond contacts of the first substrate 102 to a corresponding plurality of bond contacts of the second substrate 102. In this way, the first substrate 102 can be electrically coupled to the second substrate 104.

The bonding operation (e.g., bonding process) can be a technique such as hybrid bonding and/or direct wafer bonding. In these examples, the bonding operation can allow for a relatively high density interconnect between the first substrate 102 and the second substrate 104 without solder bumps or other adhesives. The bonding operation can include a plurality of steps to electrically couple the first bond contact 106-1 to the second bond contact 106-2. The plurality of steps can include a surface preparation step, a surface activation step, an alignment step, a contact bonding step, and an electrical testing step.

The surface preparation step can be utilized to planarize the bond contacts 106-1, 106-2 of the substrates 102, 104. The surface preparation step can ensure a high level of flatness and/or a relatively flat surface area for the bonding between the first bond contact 106-1 and the second bond contact 106-2. The planarization of the bond contacts 106-1, 106-2 can be performed utilizing a chemical-mechanical polishing (CMP) technique or similar polishing technique.

The surface activation step can be performed to alter the surface energy of the bond contacts 106-1, 106-2 in order to promote better adhesion between the bond contacts 106-1, 106-2. The activation step can include performing a plasma treatment on the surfaces of the bond contacts 106-1, 106-2 to activate the bond contacts 106-1, 106-2 and/or remove remaining organics contaminants.

The alignment step can be performed to align the surfaces of the bond contacts 106-1, 106-2 as closely as possible to ensure a high level of electrical conductivity between the first substrate 102 and the second substrate 104 through the coupled bond contacts 106-1, 106-2.

The bonding step can be performed by bringing the bond contacts 106-1, 106-2 into contact in a clean environment. As described herein, bringing the bond contacts 106-1, 106-2 into contact can create an electrostatic discharge 108. Bringing the bond contacts 106-1, 106-2 into contact can create a contact bond between the first bond contact 106-1 and the second bond contact 106-2 such that electricity can pass from the first substrate 102 to the second substrate 104 via the bonded bond contacts 106-1, 106-2. The electrical connection can be determined through the electrical testing step to ensure that the bonded bond contacts 106-1, 106-2 allow for an electrical pathway with relatively low resistance.

The first substrate 102 can be a memory die and the second substrate 104 can be a CMOS die that can be bonded together utilizing a hybrid bond contact at the first bond contact 106-1 and the second bond contact 106-2. As used herein, a memory die can refer to a semiconductor component that contains an array of memory cells organized in rows and columns. The memory die can be responsible for storing data in electronic devices. The primary function of the memory die can be to provide high-density storage capacity and fast data access.

As used herein, a Complementary Metal-Oxide-Semiconductor (CMOS) die is a type of semiconductor die that incorporates CMOS technology, which is widely used for constructing integrated circuits. CMOS technology is known for its low power consumption and high noise immunity. In a specific example, the CMOS die can be utilized as a controller or logic interface with the memory array die.

The first bond contact 106-1 and the second bond contact 106-2 can be hybrid bond contacts that can create direct bonding between the first substrate 102 and the second substrate 104. Hybrid bond contacts can be utilized for a hybrid bonding operation. A hybrid bonding operation can combine aspects of both direct bonding and traditional metal-to-metal bonding, providing electrical, thermal, and mechanical connectivity without the use of large solder bumps or wire bonds.

The second device 100-2 can include similar elements as the first device 100-1. For example, the second device 100-2 can include a first substrate 110 with a first bond contact 114-1 and a second substrate 112 with a second bond contact 114-2 that can create an electrostatic discharge 116 in response to the first bond contact 114-1 contacting the second bond contact 114-2. In contrast to the first device 100-1, the second device 100-2 can have through silicon vias (TSV) as the first bond contact 114-1 and the second bond contact 114-2 instead of hybrid bond contacts. As used herein, a TSV can refer to a vertical electrical connection that passes through a silicon wafer or die, providing a direct electrical path between different layers or dies in a stacked semiconductor device. TSV technology is utilized in 3D integrated circuits (3D ICs), enabling high-performance and high-density interconnections in electronic devices. In some examples, a first plurality of TSVs can be positioned along a first perimeter of a first die and a second plurality of TSVs can be positioned along a second perimeter of a second die.

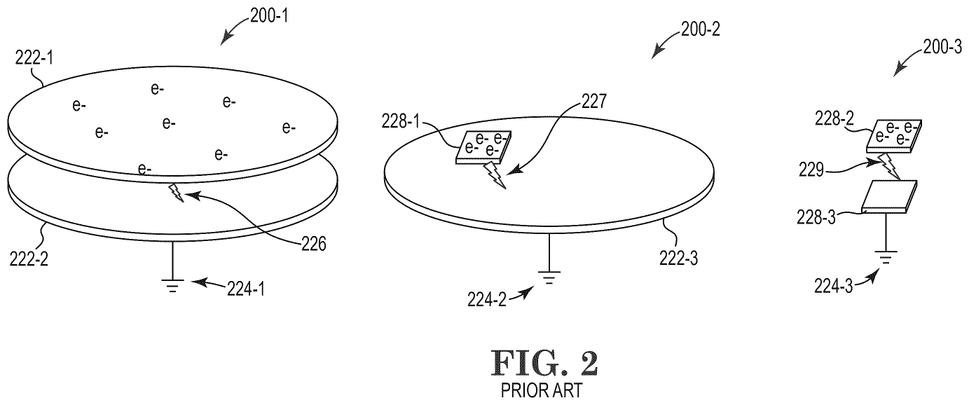

FIG. 2 is a prior art block diagram of devices 200-1, 200-2, 200-3 to illustrate an electrostatic discharge 226, 227, 229 between bonding contacts. FIG. 2 illustrates a first device 200-1 to illustrate a first type of bonding, a second device 200-2 to illustrate a second type of bonding, and a third device 200-3 to illustrate a third type of bonding. These three different types of bonding can each create a corresponding electrostatic discharge 226, 227, 229. For example, each of the corresponding electrostatic discharges 226, 227, 229 can generate different levels of voltage and/or current. Furthermore, the different devices 200-1, 200-2, 200-3 can be damaged by different levels of voltage and/or current.

The first device 200-1 can represent a wafer-to-wafer bonding where a first wafer 222-1 is electrically coupled to a second wafer 222-2. As used herein, wafer-to-wafer bonding refers to bonding two entire wafers together to form a single, unified structure. This process can be utilized in the production of three-dimensional (3D) integrated circuits (3D ICs), Micro-Electro-Mechanical Systems (MEMS), and various other advanced semiconductor devices. An electrostatic discharge 226 can be generated in response to the first wafer 222-1 contacting the second wafer 222-2. The second wafer 222-2 is illustrated as being grounded, as indicated by the ground symbol 224-1, while the first wafer 222-1 is not. Instead, the first wafer 222-1 is illustrated as carrying an electrostatic charge as indicated by the electron symbols (“e-”). This convention is used merely to illustrate the potential for electrostatic discharge between components rather than illustrating definitive electrical connections. The same is true for the ground symbols 224-2, 224-3 and electron symbols associated with dies 228-1, 228-2.

The second device 200-2 can represent a die-to-wafer bonding where a die 228-1 is bonded to a wafer 222-3. A die-to-wafer bonding can refer to bonding a die 228-1 to a surface of the wafer 222-3. As used herein, die-to-wafer bonding refers to bonding individual dies (e.g., chips, die 228-1) to a larger wafer (e.g., wafer 222-3, which can then undergo further processing steps. This method can be utilized when creating 3D integrated circuits (3D ICs) and other high-performance, high-density memory devices. An electrostatic discharge 227 can be generated in response to the die 228-1 making contact with the surface of the wafer 222-3.

The third device 200-3 can represent a die-to-die bonding where a first die 228-2 is bonded to a second die 228-3. As used herein, die-to-die bonding refers to connecting two semiconductor dies directly, without involving an intermediary wafer. This technique is utilized in creating advanced multi-chip modules (MCMs), 3D integrated circuits (3D ICs), and other high-density, high-performance semiconductor devices. An electrostatic discharge 229 can be generated in response to the first die 228-2 making contact with the second die 228-3.

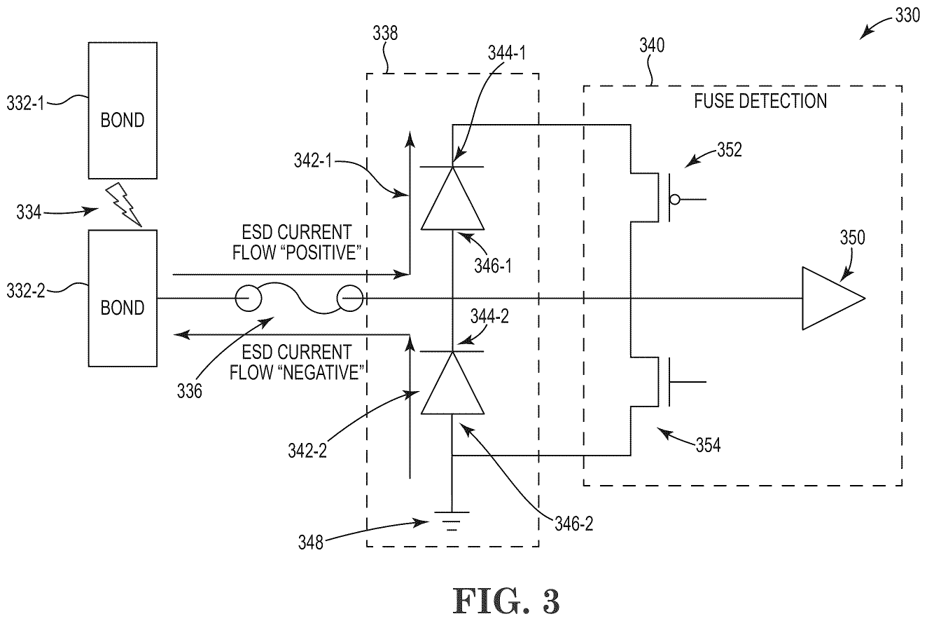

FIG. 3 illustrates an example of a system 330 that utilizes a bidirectional electrostatic discharge detector in accordance with some embodiments of the present disclosure. In this example, the bidirectional electrostatic discharge detector is on-die and is able to detect an electrostatic discharge 334 between a first bond contact 332-1 and a second bond contact 332-2. As illustrated herein, the first bond contact 332-1 and the second bond contact 332-2 can be hybrid bonds or TSV bonds depending on the application. As described herein, the first bond contact 332-1 can be coupled to a first substrate and the second bond contact 332-2 can be coupled to a second substrate. The first bond contact 332-1 can be bonded to the second bond contact 332-2 to provide an electrical connection between the first substrate and the second substrate.

The system 330 can include a fuse 336 (e.g., bidirectional fuse) electrically coupled between the second bond contact 332-2 and a bidirectional electrostatic discharge (ESD) element 338. In these embodiments, the ESD element 338 can be coupled to a detector 340. The detector 340 can be a fuse detector to determine a status of the fuse 336 during bonding operations that intend to bond the first bond contact 332-1 to the second bond contact 332-2. In these embodiments, the electrical current of the electrostatic discharge 334 generated between the first bond contact 332-1 and the second bond contact 332-2 can be received by the fuse 336 and pass through the ESD element 338. In these embodiments, the detector 340 can determine the status of the fuse 336. For example, the detector 340 can determine whether the fuse 336 blows or remains intact. Although embodiments are described herein with the use of a fuse 336, one of ordinary skill in the art could apply these teachings to the use of an antifuse rather than a fuse.

As used herein, the fuse 336 can refer to a device designed to protect electrical circuits from overcurrent, which can cause damage to equipment or create fire hazards. The fuse 336 can operate by interrupting the flow of electricity in response to the current exceeding a specific threshold current magnitude, preventing damage to the electrical system.

The fuse element can be configured to blow in response to the current of the electrical discharge 334 exceeding a threshold current magnitude. As described further herein, the threshold current magnitude can be selected based on a type of bond between the first bond contact 332-1 and the second bond contact 332-2, a type of substrate associated with the first bond contact 332-1 and/or the second bond contact 332-1, components associated with the first bond contact 332-1 and/or second bond contact 332-2, among other factors that can affect how much current and/or voltage from the electrostatic discharge 334 affects the components of the memory device.

In some embodiments, the ESD element 338 can include a first diode 342-1 and a second diode 342-2 to allow current to flow in a first direction and current to flow in a second direction. For example, the first diode 342-1 can be coupled to the fuse 336 at a cathode 346-1 and the second diode 342-2 can be coupled to the fuse 336 at an anode 344-2. In this example, the first diode 342-1 can be coupled to the fuse 336 at the cathode 346-1 and coupled to the detector 340 at the anode 344-1. In this example, the second diode 342-2 can be coupled to the fuse 336 at the anode 344-2 and coupled to the detector at the cathode 346-2. In this way, the current can flow through the fuse 336 to the first diode 342-1 and to the detector 340. In a similar way, a current can flow from the detector 340 though the second diode 342-2 to the fuse 336. In this way, the fuse 336 can be utilized to determine that the electrostatic discharge 334 exceeded a threshold current magnitude, which can negatively affect the memory device.

In some embodiments, the detector 340 can include circuitry to allow for the bidirectional current to pass through the fuse 336. For example, the detector 340 can include a P-channel Metal-Oxide-Semiconductor Field-Effect Transistor (MOSFET) 352, a N-channel MOSFET 354, and/or a receiver 350. In some embodiments, the receiver 350 can be an operational amplifier to amplify the voltage or current difference that can be created when the fuse 336 blows. In this way, the receiver 350 can be utilized to help identify that the fuse 336 has broken, which can indicate that components associated with the substrate of the first bond contact 332-1 or the components associated with the substrate of the second bond contact 332-2 are damaged.

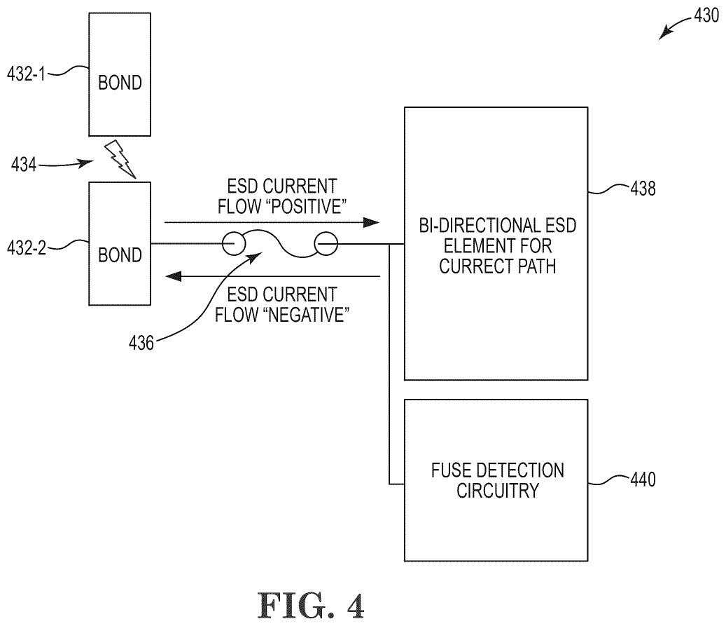

FIG. 4 illustrates an example of a system 430 that utilizes a bidirectional electrostatic discharge detector in accordance with some embodiments of the present disclosure. The system 430 can include the same or similar elements as system 330 as illustrated in FIG. 3. For example, the system 430 can include a fuse 436 that is electrically coupled to a second bond contact 432-2 to receive an electrical current generated by an electrostatic discharge 434 that is caused by a contact between a first bond contact 432-1 and the second bond contact 432-2.

In addition, the system 430 can include a bidirectional ESD element 438 to act as a current pathway. Furthermore, the system 430 can include fuse detection circuitry 440 to determine that the fuse 436 is broken by a current that exceeds a designated threshold current magnitude of the fuse 436. The fuse detection circuitry 440 can be a detector that indicates a pass or fail of a bonding operation between the first bond contact 432-1 and the second bond contact 432-2. For example, the fuse detection circuitry 440 can indicate a pass or a successful bonding operation in response to the fuse 436 not being broken by the bonding operation. In contrast, the fuse detection circuitry 440 can indicate a fail or failed bonding operation in response to the fuse 436 being broken by the bonding operation.

In some embodiments, the system 430 includes a fuse 436 coupled between a bidirectional electrostatic discharge (ESD) element 438 and a second bond contact 432-2 to receive an ESD discharge 434 current generated between the first bond contact 432-1 and the second bond contact 432-2. In these embodiments, the fuse 436 can blow in response to receiving a threshold current magnitude that is based on a type of bond formed between the first bond contact 432-1 and the second bond contact 432-2.

In some embodiments, the fuse detection circuitry 440 can be coupled to the bidirectional ESD element 438 and/or coupled between the bidirectional ESD element 438 and the fuse 436 to determine a state of the fuse 436. The state of the fuse 436 can refer to the fuse 436 being in one of an intact state (e.g., non-broken state, fuse element is not broken etc.) or a broken state (e.g., fuse element is broken). As described herein, the fuse 436 can be tuned or configured to blow in response to a fuse element receiving a current that exceeds or meets the threshold current magnitude.

In some embodiments, the threshold current magnitude is based on an ESD discharge 434 current that is capable of damaging components associated with the first bond contact 432-1 and the second bond contact 432-2. For example, the first bond contact 432-1 can be coupled to a memory die or a memory wafer that includes electrical components that can be damaged by a particular level of current. In this way, the fuse 436 can be tuned or configured to blow in response to the ESD discharge 434 exceeding that particular level of current. In these embodiments, the fuse 436 can be configured specifically for the type of bonds to be created and/or the type of components associated with the first bond contact 432-1 and the second bond contact 432-2.

In some embodiments, the first bond contact 432-1 and the second bond contact 432-2 are one of a wafer bond contact or a die bond contact of a memory device. As described herein, the type of bond can correspond to the threshold current magnitude to be utilized when configuring the fuse element of the fuse 436. For example, a first threshold current magnitude can be utilized when the first bond contact 432-1 is a hybrid bond contact of a first wafer and the second bond contact 432-2 is a hybrid bond contact of a second wafer. In this example, a second threshold current magnitude can be utilized when the first bond contact 432-1 is a TSV bond contact of a first memory die and the second bond contact 432-2 is a TSV bond contact of a second memory die. Thus, different combinations of bond types and/or substrate types can utilize different threshold current magnitudes for configuring or tuning the fuse element of the fuse 436.

In some embodiments, the bidirectional ESD element 438 includes a first device to receive a current flow from the fuse 436 and a second device to receive a current flow from the fuse 436. As described herein, the first device can be a first diode coupled to the fuse 436 at a cathode of the first diode and the second device can be a second diode coupled to the fuse 436 at an anode of the second diode.

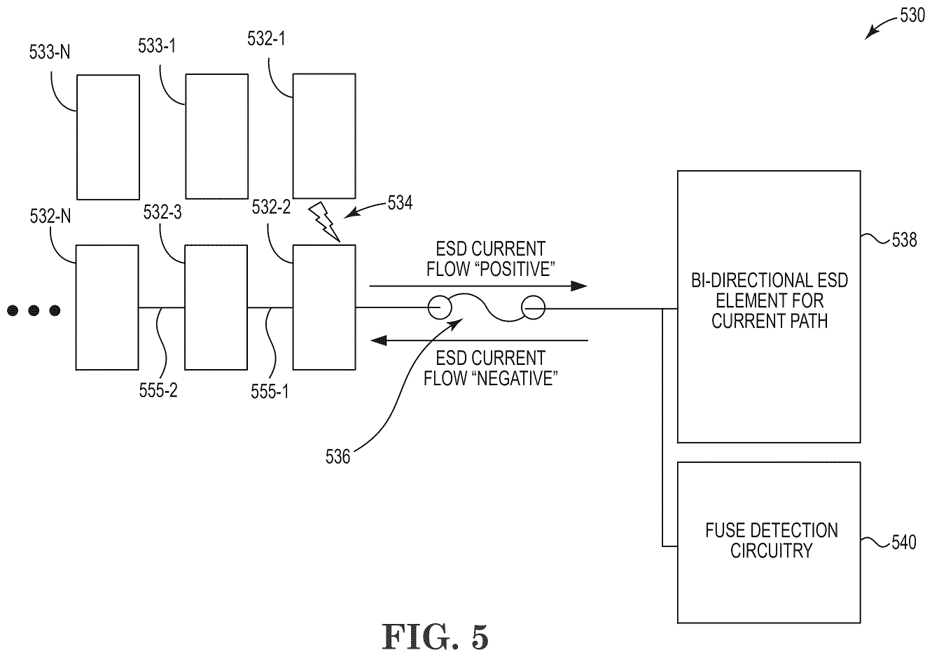

FIG. 5 illustrates an example of a system 530 that utilizes a bidirectional electrostatic discharge detector in accordance with some embodiments of the present disclosure. In some embodiments, the system 530 can include the same or similar elements as system 330 as illustrated in FIG. 3 and/or system 430 as illustrated in FIG. 4. For example, the system 530 can include a fuse 536 that is electrically coupled to a second bond contact 532-2 to receive an electrical current generated by an electrostatic discharge 534 that is caused by a contact between a first bond contact 532-1 and the second bond contact 532-2. In some embodiments, the first bond contact 532-1 can be associated with a plurality of additional contacts 533-1, 533-N. However, the first bond contact 532-1 may not be electrically connected to the other additional contacts 533-1, 533-N.

In addition, the system 530 can include a bidirectional ESD element 538 to act as a current pathway. Furthermore, the system 530 can include fuse detection circuitry 540 to determine that the fuse 536 is broken by a current that exceeds a designated threshold current magnitude of the fuse 536. In some embodiments, the fuse detection circuitry 540 can be a detector that indicates a pass or fail of a bonding operation between the first bond contact 532-1 and the second bond contact 532-2.

In some embodiments, the system 530 can include a plurality of bond contacts 532-2, 532-3, 532-N that can be connected in parallel by a plurality of connections 555-1, 555-2. As used herein, connected in parallel refers to an electrical connection where a voltage of the circuit is the same or close to the same for each component and/or the current is the sum of the individual currents of each component. In this way, the sum of the individual currents for each of the plurality of bond contacts 532-2, 532-3, 532-N can be provided to the fuse 536 and the threshold current magnitude utilized to tune or configure the fuse 536 can be based on a total current of all of the plurality of bond contacts 532-2, 532-3, 532-N.

In some embodiments, the electrical discharge 534 can be generated by a contact between the first bond contact 532-1 and the second bond contact 532-2. However, as described further herein, the electrical discharge 534 can be generated by an interaction between the first bond contact 532-1 and one of the other plurality of bond contacts 532-2, 532-3, 532-N. For example, the first bond contact 532-1 can interact with bond contact 532-3. In this example, the electrical current from the electrical discharge 534 can pass through the electrical connection 555-1 to the second bond contact 532-2 and then pass to the fuse 536.

In another example, one of the additional contacts 533-1, 533-N can interact with one of the plurality of bond contacts 532-2, 532-3, 532-N and generate a different electrical discharge (e.g., electrical discharge 534, etc.). In this way, the electrical current generated between the first bond contact 532-1 and any one of the other bond contacts 532-2, 532-2, 532-N can be provided to the fuse 536 and utilized to determine whether the generated electrical current exceeds a threshold current magnitude.

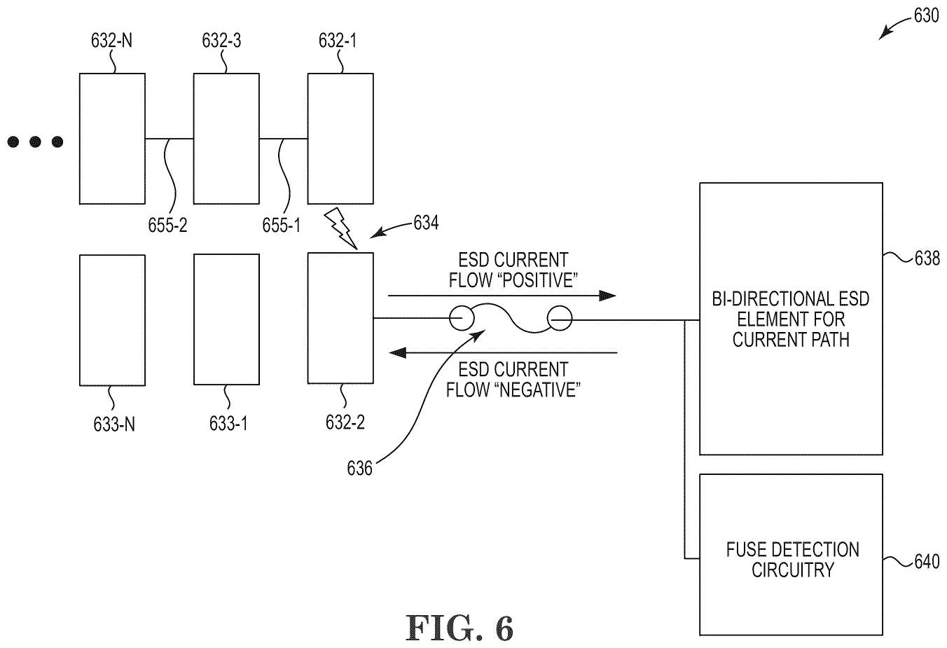

FIG. 6 illustrates an example of a system 630 that utilizes a bidirectional electrostatic discharge detector in accordance with some embodiments of the present disclosure. In some embodiments, the system 630 can include the same or similar elements as system 330 as illustrated in FIG. 3, system 430 as illustrated in FIG. 4, and/or system 530 as illustrated in FIG. 5. For example, the system 630 can include a fuse 636 that is electrically coupled to a second bond contact 632-2 to receive an electrical current generated by an electrostatic discharge 634 that is caused by a contact between a first bond contact 632-1 and the second bond contact 632-2. In some embodiments, the second bond contact 632-2 can be associated with a plurality of additional contacts 633-1, 633-N. However, the second bond contact 632-2 may not be electrically connected to the other additional contacts 633-1, 633-N.

In addition, the system 630 can include a bidirectional ESD element 638 to act as a current pathway. Furthermore, the system 630 can include fuse detection circuitry 640 to determine that the fuse 636 is broken by a current that exceeds a designated threshold current magnitude of the fuse 636. In some embodiments, the fuse 636 is a bidirectional fuse that is configured to blow at a positive threshold current magnitude and at a negative threshold current magnitude. In some embodiments, the fuse detection circuitry 640 can be a detector that indicates a pass or fail of a bonding operation between the first bond contact 632-1 and the second bond contact 632-2.

In some embodiments, the system 630 can include a plurality of bond contacts 632-1, 632-3, 632-N that can be connected in parallel by a plurality of connections 655-1, 655-2. As used herein, connected in parallel refers to an electrical connection where a voltage of the circuit is the same or close to the same for each component and/or the current is the sum of the individual currents of each component. In this way, the sum of the individual currents for each of the plurality of bond contacts 632-1, 632-3, 632-N can be provided to the fuse 636 and the threshold current magnitude utilized to tune or configure the fuse 636 can be based on a total current of all of the plurality of bond contacts 632-1, 632-3, 632-N.

In some embodiments, the electrical discharge 634 can be generated by a contact between the first bond contact 632-1 and the second bond contact 632-2. However, as described further herein, the electrical discharge 634 can be generated by an interaction between the second bond contact 632-2 and one of the other plurality of bond contacts 632-1, 632-3, 632-N. For example, the second bond contact 632-2 can interact with bond contact 632-3. In this example, the electrical current from the electrical discharge 634 can pass through the electrical connection 655-1 to the first bond contact 632-1 and then pass to the fuse 636. In this way, the electrical current generated between the second bond contact 632-1 and any one of the other bond contacts 632-1, 632-3, 632-N can be provided to the fuse 636 and utilized to determine whether the generated electrical current exceeds a threshold current magnitude.

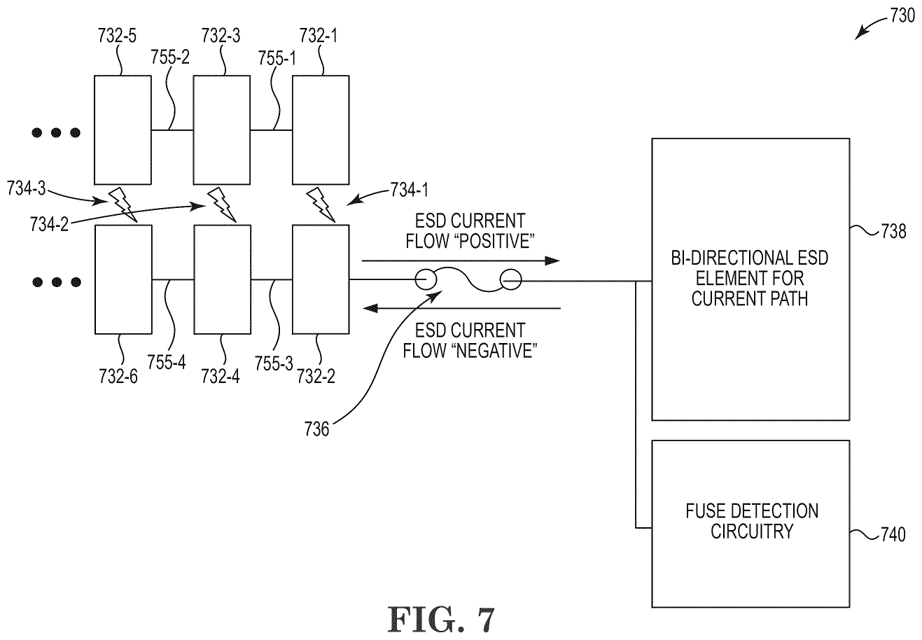

FIG. 7 illustrates an example of a system 730 that utilizes a bidirectional electrostatic discharge detector in accordance with some embodiments of the present disclosure. In some embodiments, the system 730 can include the same or similar elements as system 330 as illustrated in FIG. 3, system 430 as illustrated in FIG. 4, system 530 as illustrated in FIG. 5, and/or system 630 as illustrated in FIG. 6. For example, the system 730 can include a fuse 736 that is electrically coupled to a second bond contact 732-2 to receive an electrical current generated by an electrostatic discharge 734-1, 734-2, 734-3 that is caused by a contact between a first bond contact 732-1 and the second bond contact 732-2, between a third bond contact 732-3 and a fourth bond contact 732-4, and/or between a fifth bond contact 732-5 and a sixth bond contact 732-6. Although a particular quantity of bond contacts are illustrated in FIG. 7, additional bond contacts can be utilized without departing from the present disclosure.

In addition, the system 730 can include a bidirectional ESD element 738 to act as a current pathway. Furthermore, the system 730 can include fuse detection circuitry 740 to determine that the fuse 736 is broken by a current that exceeds a designated threshold current magnitude of the fuse 736. In some embodiments, the fuse 736 includes a first connector coupled to the one of the first plurality of bond contacts 732-1, 732-3, 732-5 (e.g., TSV bond contacts, hybrid bond contacts, etc.) and a second connector coupled to the bidirectional ESD element 738. In these embodiments, the second connector of the fuse 736 is coupled to a cathode of a first diode of the bidirectional ESD element 738 and coupled to an anode of a second diode of the bidirectional ESD element 738.

In some embodiments, the fuse detection circuitry 740 can be a detector that indicates a pass or fail of a bonding operation between a first bond contact 732-1 and the second bond contact 732-2, between a third bond contact 732-3 and a fourth bond contact 732-4, and/or between a fifth bond contact 732-5 and a sixth bond contact 732-6.

In some embodiments, the system 730 can include a first plurality of bond contacts 732-1, 732-2, 732-5 coupled to a first substrate that can be connected in parallel by a plurality of connections 755-1, 755-2. In addition, the system 730 can include a second plurality of bond contacts 732-2, 732-4, 732-6 coupled to a second substrate that can be connected in parallel by a plurality of connections 755-3, 755-4. As used herein, connected in parallel refers to an electrical connection where a voltage of the circuit is the same or close to the same for each component and/or the current is the sum of the individual currents of each component.

In this way, the sum of the individual currents for each of the first plurality of bond contacts 732-1, 732-2, 732-5 and/or the sum of the individual currents for each of the second plurality of bond contacts 732-2, 732-4, 732-6 can be provided to the fuse 736 and the threshold current magnitude utilized to tune or configure the fuse 736 can be based on a total current of all of the first plurality of bond contacts 732-1, 732-2, 732-5 and/or the sum of the individual currents for each of the second plurality of bond contacts 732-2, 732-4, 732-6.

In some embodiments, the threshold current magnitude utilized to configure or tune the fuse 736 can be based on a quantity of first plurality of bond contacts 732-1, 732-2, 732-5 and/or a quantity of the second plurality of bond contacts 732-2, 732-4, 732-6. For example, the quantity of bond contacts can be utilized to determine an acceptable current value of a single bond contact or an acceptable sum current value from all of the bond contacts. In some embodiments, the threshold current magnitude can be based on a quantity of interactions between the first plurality of bond contacts 732-1, 732-2, 732-5 and the second plurality of bond contacts 732-2, 732-4, 732-6.

In a specific embodiment, the system 730 can include a first plurality of through silicon vias (TSVs) coupled to a first wafer. In this embodiment, the first plurality of TSVs are electrically coupled in a parallel connection by the plurality of connections 755-1, 755-2. In these embodiments, the system 730 can include a second plurality of TSVs coupled to a second wafer. In these embodiments, the second plurality of TSVs are electrically coupled in a parallel connection by the plurality of connections 755-3, 755-4. In some embodiments, the ESD received from the plurality of TSVs through the fuse 738 includes ESD received through the parallel connection of the second plurality of TSV bond contacts 732-2, 732-4, 732-6 when the first plurality of TSV bond contacts 732-1, 732-3, 732-5 are coupled to the second plurality of TSV bond contacts 732-2, 732-4, 732-6 through a bonding process.

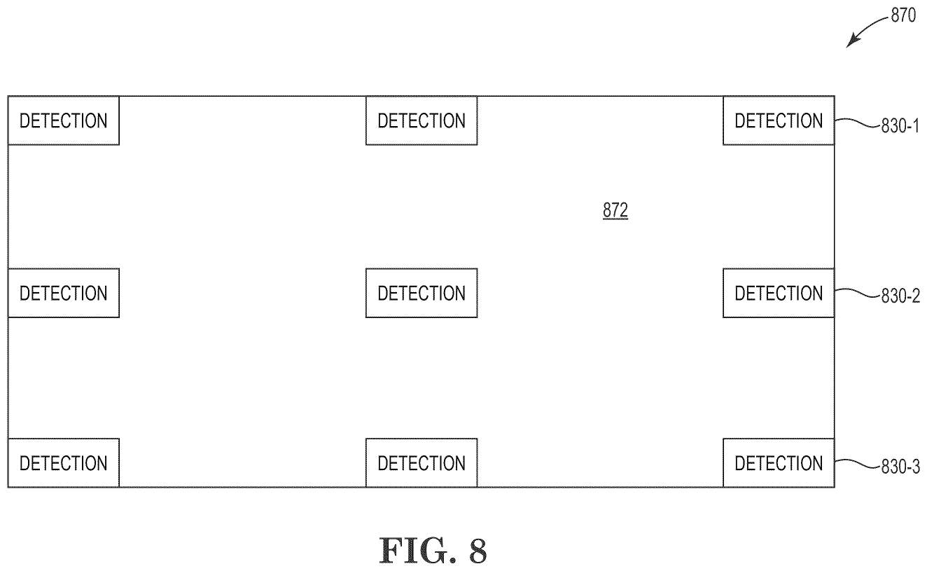

In some embodiments, the first plurality bond contacts 732-1, 732-3, 732-5 are positioned along a first perimeter of the first wafer and the second plurality bond contacts 732-2, 732-4, 732-6 are positioned along a second perimeter of the second wafer. As illustrated in FIG. 8, the system 730 can be located along a perimeter of one of the first wafer or a second wafer.

In some embodiments, a first electrical discharge 734-1 can be generated by a contact between the first bond contact 732-1 and the second bond contact 732-2. In these embodiments, a second electrical discharge 734-2 can be generated by a contact between the third bond contact 732-3 and the fourth bond contact 732-4. In these embodiments, a third electrical discharge 734-3 can be generated by a contact between the fifth bond contact 732-5 and the sixth bond contact 732-6. In these embodiments, the first electrical discharge 734-1 can have a first current, the second electrical discharge 734-2 can have a second current, and the third electrical discharge 734-3 can have a third current. In these embodiments, the sum of the first current, second current, and third current can be provided to the fuse 736 and the fuse detection circuitry 740 can be utilized to determine that the sum of the first current, second current, and third current exceed a threshold current magnitude level of the fuse 736.

FIG. 8 illustrates an example of a system 870 that utilizes a plurality of bidirectional electrostatic discharge detectors in accordance with some embodiments of the present disclosure. In some embodiments, the system 870 illustrates a substrate 872 that includes a plurality of detection systems 830-1, 830-2, 830-N. The plurality of detection systems 830-1, 830-2, 830-N can each include the same or similar elements as system 330 as illustrated in FIG. 3, system 430 as illustrated in FIG. 4, system 530 as illustrated in FIG. 5, system 630 as illustrated in FIG. 6 and/or system 730 as illustrated in FIG. 7. For example, the plurality of detection systems 830-1, 830-2, 830-N can each include circuitry to determine whether an electrical discharge is generated by contact between a first bond contact and a second bond contact.

In some embodiments, the plurality of detection systems 830-1, 830-2, 830-N can be positioned along a perimeter of the substrate 872 and/or in areas within the interior of the substrate 872. In some embodiments, the plurality of detection systems 830-1, 830-2, 830-N can be positioned in areas of the substrate 872 that include bond contacts to be utilized for bonding with a different substrate.

In some embodiments, the substrate 872 can be a silicon die substrate, a wafer substrate, or other type of electrical substrate. In this way, the plurality of detection systems 830-1, 830-2, 830-N can be positioned or described as being positioned on-die. Having the plurality of detection systems 830-1, 830-2, 830-N positioned on-die can save space and provide for a more accurate determination of whether the substrate 872 has been damaged during a bonding operation. As used herein, positioned on-die can refer to components that are fabricated on the same semiconductor die.

In some embodiments, the components of the plurality of detection systems 830-1, 830-2, 830-N can be resident on the substrate 872. As used herein, the term “resident on” refers to something that is physically located on a particular component. The term “resident on” may be used interchangeably with other terms such as “deployed on” or “located on,” herein.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory devices, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. An apparatus, comprising:
a fuse coupled between a bidirectional electrostatic discharge (ESD) element and a first bond contact;
wherein the fuse is configured to receive an ESD discharge current generated between the first bond contact and a second bond contact; and
wherein the fuse is configured to blow in response to the ESD discharge current exceeding a threshold current magnitude; and
a detector coupled to the bidirectional ESD element, wherein the detector is configured to determine a state of the fuse.

2. The apparatus of claim 1, wherein the threshold current magnitude corresponds to ESD discharge current that is capable of damaging components associated with the first bond contact and the second bond contact.

3. The apparatus of claim 1, wherein the first bond contact and the second bond contact are one of a wafer-to-wafer bond contact, a die-to-wafer bond contact, and a die-to-die bond contact of a memory device.

4. The apparatus of claim 1, wherein the bidirectional ESD element includes a first device configured to receive a current flow from the fuse and a second device configured to provide a current flow to the fuse.

5. The apparatus of claim 4, wherein the first device is a first diode coupled to the fuse at a cathode of the first diode and the second device is a second diode coupled to the fuse at an anode of the second diode.

6. The apparatus of claim 1, wherein the detector is configured to indicate a pass or fail of a bonding operation between the first bond contact and the second bond contact.

7. An apparatus, comprising:
a fuse coupled to a bond contact of a first substrate, wherein the first substrate includes a first plurality of bond contacts;
a bidirectional electrostatic discharge (ESD) element configured to provide a bidirectional current path through the fuse from the first plurality of bond contacts; and
a detector configured to determine a state of the fuse in response to receiving an ESD discharge current from the bond contact;
wherein the ESD discharge current is generated by an interaction between the bond contact and a corresponding bond contact of a second plurality of bond contacts coupled to a second substrate.

8. The apparatus of claim 7, wherein the bond contact is electrically coupled in parallel to the first plurality of bond contacts.

9. The apparatus of claim 7, wherein the second plurality of bond contacts are electrically coupled in parallel.

10. The apparatus of claim 8, wherein the detector includes a P-channel Metal-Oxide-Semiconductor Field-Effect Transistor (MOSFET), a N-channel MOSFET, and a receiver.

11. The apparatus of claim 10, wherein the bidirectional ESD element includes a first diode that includes an anode coupled to the P-channel MOSFET and a second diode that includes a cathode coupled to the N-channel MOSFET.

12. The apparatus of claim 11, wherein the first diode includes a cathode coupled to the fuse and the second diode includes an anode coupled to the fuse.

13. The apparatus of claim 7, wherein the bidirectional ESD element is resident on one of the first substrate and the second substrate.

14. A device, comprising:
a first plurality of through silicon vias (TSVs) coupled to a first wafer, wherein the first plurality of TSVs are electrically coupled in a parallel connection;
a second plurality of TSVs coupled to a second wafer, wherein the second plurality of TSVs are electrically coupled in a parallel connection;
a fuse electrically coupled to one of the first plurality of TSVs;
a bidirectional electrostatic discharge (ESD) element coupled to the fuse to provide a bidirectional current path for ESD received from the one of the first plurality of TSVs through the fuse, wherein the ESD is generated by an interaction between at least one of the first plurality of TSVs and the second plurality of TSVs; and
a detector coupled between the fuse and the bidirectional ESD element to determine a status of the fuse.

15. The device of claim 14, wherein the fuse includes a first connector coupled to the one of the first plurality of TSVs and a second connector coupled to the bidirectional ESD element.

16. The device of claim 15, wherein the second connector of the fuse is coupled to a cathode of a first diode of the bidirectional ESD element and coupled to an anode of a second diode of the bidirectional ESD element.

17. The device of claim 14, wherein the fuse is a bidirectional fuse that is configured to blow at a positive threshold current and at a negative threshold current.

18. The device of claim 14, wherein the ESD received from the one of the first plurality of TSVs through the fuse includes ESD received through the parallel connection of the first plurality of TSVs when the first plurality of TSVs are coupled to the second plurality of TSVs through a bonding process.

19. The device of claim 14, wherein the first plurality of TSVs are positioned along a first perimeter of a first die and the second plurality of TSVs are positioned along a second perimeter of a second die.

20. The device of claim 14, wherein the bidirectional ESD element is located on-die of a memory device.
